(19) United States
(12) Patent Application Publication
(10) Pub. No.: US 2014/0175479 A1
(43) Pub. Date: Jun. 26, 2014

(54) LED UNIT WITH LIGHT MIXING ELEMENT

(71) Applicant: HON HAI PRECISION INDUSTRY CO., LTD., New Taipei (TW)

(72) Inventor: CHEN-HAN LIN, New Taipei (TW)

(21) Appl. No.: 13/926,174

(22) Filed: Jun. 25, 2013

(30) Foreign Application Priority Data
Dec. 24, 2012 (TW) 101149446

(51) Int. Cl. H01L 33/50

(52) U.S. Cl. CPC H01L 33/505
USPC 257/98

(57) ABSTRACT

An LED unit includes an LED, a light mixing element mounted on the LED and a lens covering the light mixing element. The light mixing element is transparent and includes a top face, a bottom face and a circumferential face. Light emitted from the LED with a large output angle is refracted by the bottom face, reflected by the circumferential face and refracted by the top face of the light mixing element to radiate out of the light mixing element with a small light emergent angle.

### BACKGROUND

1. Technical Field

The disclosure generally relates to an LED (light emitting diode) unit, and more particularly, to an LED unit with a light mixing element.

2. Description of Related Art

Nowadays LEDs (light emitting diodes) are applied widely in displays for illumination. A type of display, generally called direct-light display, uses a plurality of LEDs to directly illuminate the screen thereof. The LED often includes a blue light-emitting chip, an encapsulant sealing the chip and a yellow phosphor layer doped in the encapsulant and covering the chip. Thus, blue light emitted from the chip can activate the phosphor to emit yellow light, which mixes with the blue light to produce white light.

However, the blue light emitted from the chip passes through the phosphor layer in different pathways. A part of the blue light having a large light-emergent angle may activate more phosphor in a long pathway to produce more yellow light, while another part of the blue light having a small light-emergent angle may activate less phosphor in a short pathway to produce less yellow light. Thus, the blue light and the yellow light cannot be mixed uniformly, resulting in a yellow ring appearing at a periphery of the white light.

Furthermore, a lens may be mounted over the LED for diffusing the white light emitted from the LED. Nevertheless, the lens has different light-refraction levels for the blue light and the yellow light. As a result, the blue light and the yellow light are refracted by the lens to be more deviated from each other, thereby causing the yellow ring to become more apparent. When such white light emitted from the LED is used to be diffused by a diffusion plate to illuminate a screen of a display such as an LCD (liquid crystal display), the color aberration of the white light causes the color of the image shown on the screen to be distorted.

What is needed, therefore, is an LED unit with a light mixing element which can address the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the various views.

FIG. 1 shows an LED unit in accordance with an embodiment of the present disclosure.

FIG. 2 is an enlarged view of part II of FIG. 1.

### DETAILED DESCRIPTION

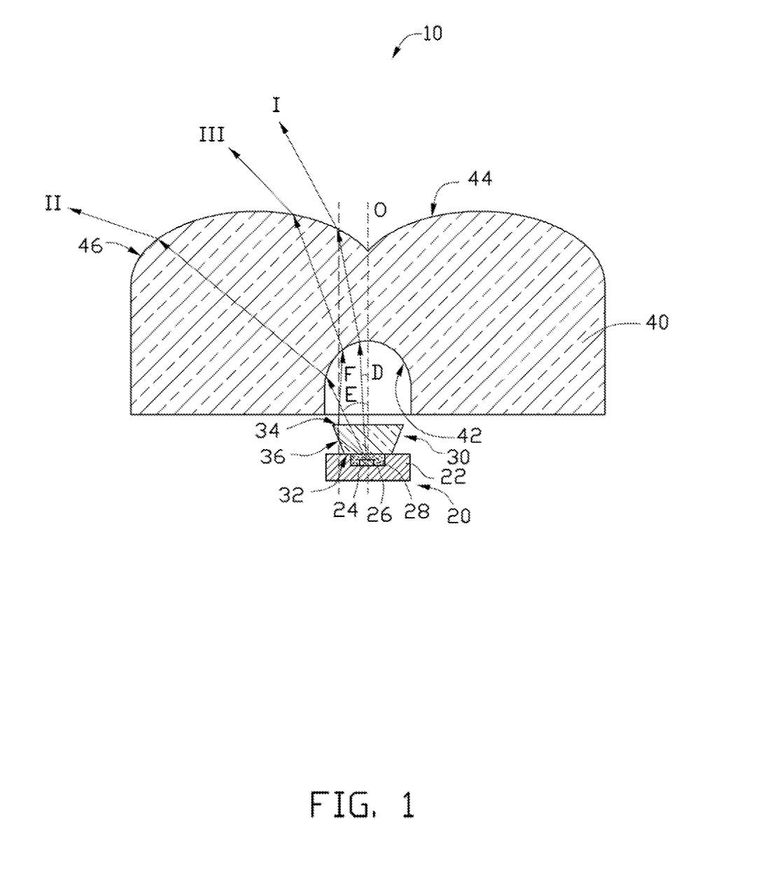

Referring to FIG. 1, an LED (light emitting diode) unit 10 in accordance with an embodiment of the present disclosure is shown. The LED unit 10 includes an LED 20, a light mixing element 30 mounted on the LED 20 and a lens 40 covering the light mixing element 30.

The LED 20 includes a base 22, a light-emitting chip 24 mounted on the base 22 and an encapsulant 26 sealing the chip 24. The base 22 may be made of heat conductive and electrical-insulating material such as ceramic. The chip 24 may be made of semiconductor material such as GaN, InGaN, AlInGaN. The chip 24 emits blue light when powered. The encapsulant 26 may be made of transparent material such as silicone, polycarbonate or polymethylmethacrylate. The base 22 defines a cavity in a top face therein. The chip 24 is received in the cavity and the encapsulant 26 is filled in the cavity to protect the chip 24 from an outside environment. The encapsulant 26 has a top face flush with that of the base 22. Phosphor 28 is doped within the encapsulant 26. The phosphor 28 may be made of yttrium aluminum garnet, silicate or other suitable materials. The phosphor 28 can be activated by the blue light to emit yellow light.

The light mixing element 30 is attached on the top face of the base 22 and the encapsulant 26. The light mixing element 30 may be made of transparent material such as epoxy, silicone, polycarbonate, polymethylmethacrylate or other suitable materials. The light mixing element 30 may have a light refractive index larger than or equal to that of the encapsulant 26. The light mixing element 30 may be attached on the LED 20 by adhesive. The light mixing element 30 has a bottom face 32 joining the LED 20, a top face 34 parallel to the bottom face 32 and a circumferential face 36 between the top face 34 and the bottom face 32. The bottom face 32 of the light mixing element 30 acts as a light incident face, and the top face 34 of the light mixing element 30 acts as a light emergent face. The bottom face 32 has an area less than that of the top face 34. The circumferential face 36 has a diameter gradually decreasing from the top face 34 towards the bottom face 32. Thus, the light mixing element 30 represents a truncated conical shape.

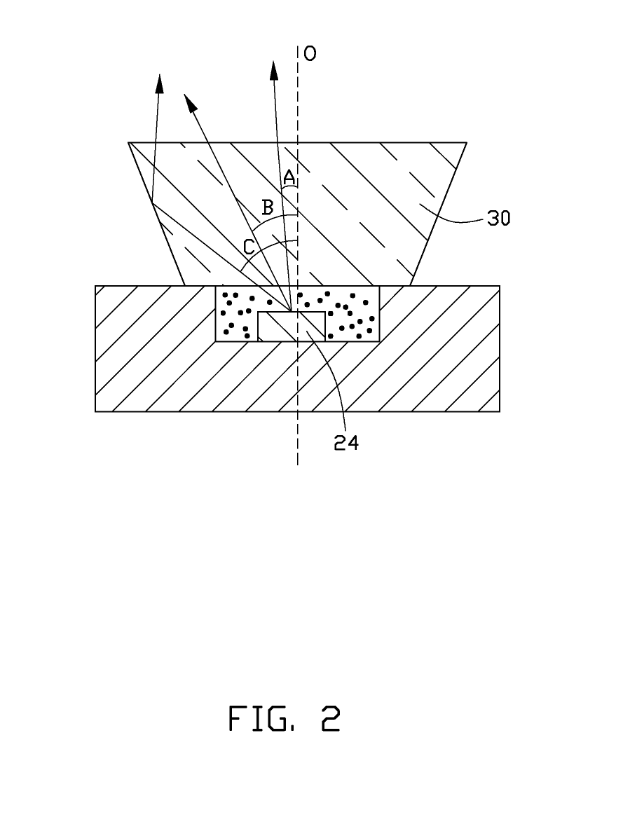

Referring also to FIG. 2, light emitted from the chip 24 is mixed within the light mixing element 30. A first part of light (such as the light I) emitted out of the LED 20 with a small light output angle A, is refracted by the bottom face 32 and the top face 34 of the light mixing element 30, to thereby emit out of the light mixing element 30 with a small light emergent angle D. A second part of light (such as the light II) emitted out of the LED 20 with a medium output angle B, is refracted by the bottom face 32 and the top face 34 of the light mixing element 30, to thereby emit out of the light mixing element 30 with a large light emergent angle E. A third part of light (such as the light III) emitted out of the LED 20 with a large output angle C, is refracted by the bottom face 32, totally reflected by the circumferential face 36 and refracted by the top face 34 of the light emitting element 30, to thereby emit out of the light mixing element 30 with a small light emergent angle F. That is to say, the third part of light which has the large output angle C when emitting out of the LED 20, is adjusted by the light mixing element 30 to deflect towards a central axis O of the LED 20. The adjusted third part of light mixes with the first part of light and second part of light adjusted by the light mixing element 30, thereby producing uniform white light. Particularly, the third part of light emitted out of the LED 20, is deflected more adjacent to the central axis O of the LED 20 than the second part of light, thereby weakening or even eliminating yellow ring appearing at a periphery of the white light.

The lens 40 is mounted over the light mixing element 30. The lens 40 may also be made of transparent material such as epoxy, silicone, polycarbonate, polymethylmethacrylate or other suitable materials. The lens 40 is a light diffusion lens. The lens 40 includes a light incident face 42 and a light emergent face 44 opposite to the light incident face 42. In this embodiment, the light incident face 42 is formed in a bottom face of the lens 40. The light incident face 42 is a curved, concave face located above the top face 34 of the light mixing element 30. The light emergent face 44 includes two convex faces 46 connecting with each other. A boundary of the two convex faces 46 is aligned with the central axis O of the LED 20. The lens 40 diffuses the light emitted out of the light mixing element 30 more widely, thereby increasing illumination area of the LED unit 10.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An LED (light emitting diode) unit comprising:
an LED comprising a base, a chip mounted on the base, an encapsulant sealing the chip and phosphor doped within the encapsulant; and
a light mixing element mounted on the LED, the light mixing element comprising a light incident face, a light emergent face and a light reflecting face between the light incident face and the light emergent face; and
a lens;
wherein light emitted out of the LED with a first light output angle is sequentially refracted by the light incident face and refracted by the light emergent face of the light mixing element to radiate out of the light mixing element with a first light emergent angle, and light emitted out of the LED with a second light output angle is sequentially refracted by the light incident face, reflected by the light reflecting face and refracted by the light emergent face of the light mixing element to radiate out of the light mixing element with a second light emergent angle, the first light output angle being less than the second light output angle, and the first light emergent angle being larger than the second light emergent angle.

2. The LED unit of claim 1, wherein the light mixing element is made of transparent material.

3. The LED unit of claim 1, wherein the light mixing element is attached on the LED by adhesive.

4. The LED unit of claim 1, wherein the light mixing element is spaced from and does not contact the lens.

5. The LED unit of claim 1, wherein the light reflecting face of the light mixing element directly connects the light incident face and the light emergent face of the light mixing element.

6. The LED unit of claim 1, wherein the light reflecting face of the light mixing element has a diameter gradually decreasing from the light emergent face towards the light incident face of the light mixing element.

7. The LED unit of claim 1, wherein the light mixing element does not contain phosphor.

8. The LED unit of claim 1, wherein the light mixing element directly connects the encapsulant.

9. The LED unit of claim 8, wherein the light mixing element further directly connects the base.

10. The LED unit of claim 1, wherein the light mixing element has a light refractive index larger than that of the encapsulant.

11. The LED unit of claim 1, wherein the light mixing element has a light refractive index equal to that of the encapsulant.

12. The LED unit of claim 1, wherein the lens comprises a light incident face adjacent to the light mixing element and a light emergent face opposite to the light incident face thereof.

13. The LED unit of claim 12, wherein the light emergent face of the lens comprises two curved, convex faces connected to each other.

14. The LED unit of claim 13, wherein a boundary of the two curved, convex faces is aligned with a central axis of the LED.

15. The LED unit of claim 12, wherein the light incident face of the lens is a curved, concave face.

16. The LED unit of claim 1, wherein the light mixing element is made of the same material as the lens.

17. The LED unit of claim 1, wherein the lens is a light diffusion lens.
